(19) United States
(12) Patent Application Publication
(10) Pub. No.: US 2022/0010668 A1
(43) Pub. Date: Jan. 13, 2022

(54) WELLBORE ISOLATION BARRIER MONITORING

(71) Applicant: Halliburton Energy Services, Inc., Houston, TX (US)

(72) Inventors: Richard Frank VARGO, JR., Katy, TX (US); James H. BERRY, Atascocita, TX (US); James Owen COLLINS, The Woodlands, TX (US)

(21) Appl. No.: 17/125,032

(22) Filed: Dec. 17, 2020

Related U.S. Application Data
(60) Provisional application No. 63/050,271, filed on Jul. 10, 2020.

(51) Int. Cl. E21B 47/007; E21B 47/113; E21B 49/00; E21B 47/005

(52) U.S. Cl. CPC E21B 47/007; E21B 47/113; E21B 47/047; E21B 47/005; E21B 49/006

(57) ABSTRACT

A method of evaluating a stress state of a wellbore isolation barrier with an evaluation application receiving a data set, obtained from wellbore sensors, from a remote data source by one or more communication methods. The data set comprises periodic wellbore data indicative of the stress state of the wellbore isolation barrier. The evaluation application may determine a modeled stress state of the wellbore isolation barrier by evaluating a data set consisting of the received data. The evaluation application may generate an alert if the model stress state exceeds a user threshold.

### CROSS-REFERENCE TO RELATED APPLICATIONS

This application claims priority under 35 U.S.C. § 119(e) to U.S. Provisional Patent Application No. 63/050,271 filed on Jul. 10, 2020 and entitled “Isolation Barrier Monitoring,” the disclosure of which is hereby incorporated herein by reference in its entirety.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

In oil and gas wells comprising a wellbore penetrating a subterranean formation, a primary purpose of a downhole barrier (e.g., a barrier formed from a composition such as cement or a sealant) is to isolate the formation fluids between zones penetrated by the wellbore, also referred to as zonal isolation and zonal isolation barriers. A barrier such as cement (also referred to as a cement sheath) is used to support a conduit disposed within the wellbore (e.g., a metal casing lining the wellbore), and the cement provides a barrier to prevent the formation fluids from damaging the casing and to prevent interzonal fluid migration along with the casing.

Typically, an oil well is drilled to a desired depth with a drill bit and mud fluid system. A conduit (e.g., casing, liner, etc.) is lowered into the drilled well to prevent the collapse of the wellbore drilled into the formation. During a primary cementing operation, a barrier composition such as cement is placed in an annulus formed between the conduit (e.g., casing) and wellbore wall to form a cement sheath. A primary cementing operation pumps a cement blend tailored for the environmental conditions of the wellbore. The primary cementing operation may utilize specialized pumping equipment on the drilling rig or transported to the drilling rig. The primary cementing operation may utilize various specialized downhole equipment such as wipers, darts, float shoes, and casing centralizers. The cement is typically pumped down the casing and back up into the annular space between the casing and wellbore wall penetrating the formation and allowed to harden into a cement sheath that forms a zonal isolation barrier.

The cement placed between the casing and the formation will isolate the casing from wellbore fluids. The primary cementing operation may isolate one or more zones or formation strata penetrated by the wellbore from undesirable fluid communication therebetween, for example, isolation between a shallow aquifer and one or more production zones downhole. The cement sheath around the casing must isolate the zones to prevent cross zone migration of formation fluids. In some wells, the production zones may be isolated with a secondary casing called a liner. The primary casing may extend partway to the target formation. The bottom of the primary casing may be drilled out and the wellbore extended to the target formation with a liner.

The casing and cement may be perforated to allow the formation fluids to be extracted. The casing and cement may be perforated in multiple locations to coincide with multiple production zones of a well. The well may be perforated with perforating gun assemblies lowered into the wellbore from the surface. The well may also be perforated with production sleeves run into the well with the casing or liner.

Often the formation fluids initially flow to the surface via the wellbore due to formation pressure in the subterranean formations. As the production of formation fluids continues, the formation pressure decreases. In a well with multiple production zones, the pressure inside one of the production zones may decrease at a faster rate than the other zones.

The monitoring of production from each zone of a wellbore is desirable as a production company may change the production rate from one zone based on a change in the wellbore environment. Furthermore, monitoring of the barrier (e.g., cement or sealant composition) is useful to ensure continued zonal isolation during the operational life of the well.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is a cut-away illustration of an embodiment of a well system.

FIG. 2 is a schematic diagram of a communication system.

FIG. 3 is a logical flow diagram depicting an automated diagnostic application according to an embodiment of the disclosure.

FIG. 4 is a logical flow diagram depicting an automated diagnostic application according to another embodiment of the disclosure.

FIG. 5 is a logical flow diagram depicting an automated diagnostic application according to still another embodiment of the disclosure.

FIG. 6 is a logical flow diagram depicting an automated diagnostic application according to yet another embodiment of the disclosure.

FIGS. 7-10 are cut-away illustrations of a well system with a liner before, during, and after cementing of the liner.

FIG. 11 is a schematic diagram of load sequences associated with events in a well life-cycle.

FIG. 12A is a schematic diagram of a communication system.

FIG. 12B is a schematic diagram of a core network.

FIG. 13 is a schematic diagram of computer system.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

The long-term effectiveness of well barriers (e.g., cement or sealant compositions) in isolating one or more production well zones has long been an area of interest. It is well known in the industry that barriers made of Portland cement and non-Portland cement change over time due to many environmental factors in a wellbore such as temperature, pressure, and corrosive fluids. In addition to environmental factors, changes in production rates, formation pressures, well shut-ins, and well stimulation may also change a cement well barrier with the additional stress applied during such well servicing operations or interventions. For example, a well shut-in may change the bottom-hole temperature of a well and the axial loading between zones. Well interventions may apply pressure to the cement well barrier and increase the stress applied, both radially and axially, to the cement barrier. The changes in the wellbore environment and applied stress from well servicing operations may lead to barrier damage or a well barrier failure. A well barrier failure is typically determined with a costly and potentially damaging well service involving one or more imaging downhole tools. Early detection of barrier damage or a cement barrier failure may help an operator or well owner diagnose the cause of the barrier damage or failure and potentially prompt remedial changes that would remediate the damage, prevent or repair the failure and prolong the life of the well.

A stress state of the barrier (e.g., cement sheath) is a determination of how much stress the barrier is experiencing. Stress is typically expressed as a measure of force per unit area, with force having both magnitude and direction. For example, the barrier may be experiencing compressive stress, tensile stress, shear stress, bending stress, torsion stress, fatigue stress, or any combination thereof.

A stress state of the barrier may be determined from data gathered from the wellbore in which the barrier is located. Data can be gathered from one or more sensors located in the wellbore proximate to or embedded within the barrier as described in more detail herein. Such data may include temperature, pressure, one or more physical or mechanical properties of the barrier, or combinations thereof. For example, a multifunctional sensor may provide a temperature sensor component to measure ambient temperature in the wellbore, a pressure sensor component to measure ambient pressure in the wellbore, and a strain gauge component to measure deformation of the cement barrier in response to one or more forces (e.g., loads) applied to the cement barrier. From the gathered data, a stress state of the barrier can be determined, for example using engineering analysis (e.g., finite element analysis) software of the type described herein.

The barrier (e.g., cement sheath) may experience loads resulting from changes in downhole ambient temperature and/or pressure. For example, as a result of fluid flowing into or from the well (including periods of changing or no fluid flow), the wellbore may experience changes in temperature and/or pressure at one or more locations along a length thereof, and such changes in temperature and/or pressure may result in expansion or contraction of the casing which exerts a related force upon the cement sheath that is in contact with the expanding or contracting casing. Also mechanical forces (e.g., loads) may be exerted on the cased wellbore (and likewise on the cement sheath in contact with the casing) during a well operation such as drilling the well, casing the well, cementing the well, pressure testing the well, completing the well, fracturing the well, logging the well, injecting fluid into the well, producing fluid from the well, shutting in the well, or any combination thereof. Such forces (e.g., loads) may be measured (e.g., via data obtained from a strain gauge in contact with the cement sheath) and/or modeled (e.g., via wellbore modeling software) and used to determine a stress state of the barrier as described herein.

A stress state of the barrier can be determined at one or more locations along a length of the barrier (e.g., 2 points located/spaced a distance apart measured along a central axis of the wellbore, also referred to as an axial length or axial distance). For example, a plurality of stress states can be determined for each of a corresponding plurality of locations spaced along a given length of the barrier, and the plurality of stress states can be used to determine a stress state profile along said given length of the barrier (e.g., stress state of the barrier as a function of barrier length). For example, a stress state profile may be determined for about 10, 20, 30, 40, 50, 60, 70, 80, 90, 95, or 100% of the length of the barrier (e.g., an axial length of a cement sheath positioned in the annulus formed by a conduit disposed along a corresponding length of a wellbore).

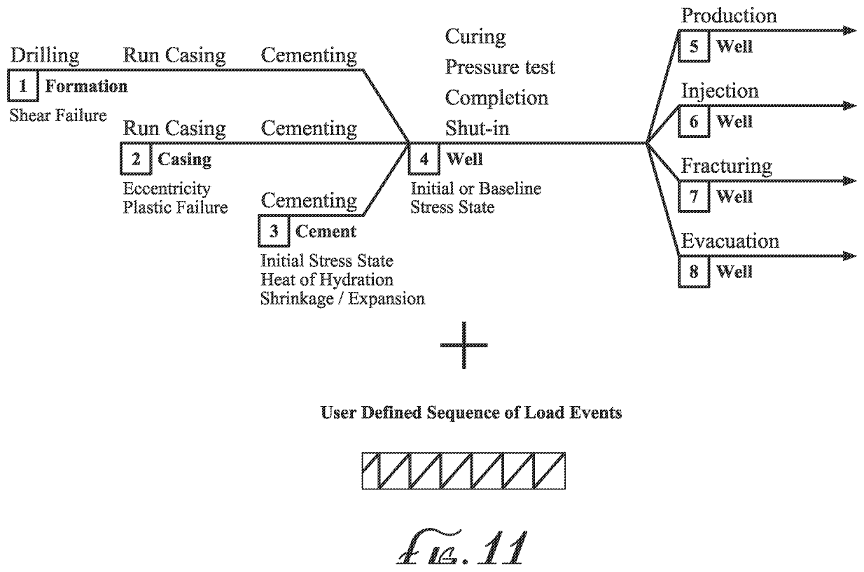

A stress state of the barrier can be determined at one or more moments or instances in time. For example, a stress state of the barrier can be determined for a given time instance, for example a given date and time. When a stress state that is determined for a given time instance that is about equal to or near the present or current date and time, such stress state may be referred to as a present, about present, current, or about current stress state of the barrier. A stress state determined at a time instance before the current date and time may be referred to as a past or previous stress state. With the passage of time, a current stress state will become a past stress state. A stress state estimated, projected, or predicted (e.g., modeled) for a time instance after the current date and time may be referred to as a future or predicted stress state. With the passage of time, a current stress state may or may not equal a predicted future stress state depending upon the accuracy of the prediction thereof. As described in more detail herein with reference to FIG. 11, the initial stress state of a given wellbore barrier may refer to the first determination of the stress state of the wellbore at or shortly after the time of completion of the wellbore (e.g., event stage 4 of FIG. 11, which is typically before commercial production commences) derived from data obtained from sensors located downhole within the wellbore.

A stress state of the barrier can be determined for an interval or period of time comprising a plurality of time instances (e.g., plurality of data sampling instances). In some embodiments, a stress state of the barrier can be determined for an interval or period of time corresponding to a plurality of data sampling instances (e.g., sampling per minute, hourly, daily, weekly, monthly, or yearly), and a stress state profile may be determined for the barrier as a function of time (e.g., a plurality of daily stress states may provide a stress state profile for the barrier as a function of time over the period comprising the plurality of daily stress states). For example, data can be gathered hourly for a 24 hour period corresponding to a current date X to provide a current stress state for date X (or about current depending upon the delay, if any, associated with processing the gathered data to determine a stress state of the barrier on date X). The current stress state for date X can be compared to a previous stress state for a date occurring prior to X to determine if there has been a change of stress state for the barrier, which may be indicative of the need for further inspection or testing of the barrier, or possibly a need for remedial action on the barrier to repair or prevent damage thereto. The current stress state for date X can be compared to a predicted stress state (e.g., a predicted stress state corresponding to the current date X and/or a predicted stress state for a future date occurring subsequent to X) to determine if there has been a change of stress state for the barrier in comparison to the predicted stress state (or a need for a change in the forecasted or predicted future stress state), which may be indicative of the need for further current and/or future inspection or testing of the barrier, or possibly a need for current and/or future remedial action on the barrier to repair or prevent damage thereto.

In some embodiments, a method of monitoring a condition (e.g., stress state) of the wellbore barrier is provided wherein one or more downhole sensors located along the wellbore proximate the barrier provides periodic data regarding the condition (e.g., stress state) of the wellbore barrier. The downhole sensors can be located in the cement well barrier located between the casing and formation. Additionally or alternatively, the sensors can be coupled to (e.g., dispersed along) the casing. These downhole sensors can provide data regarding one or more ambient conditions in the wellbore proximate the cement barrier, such as the pressure and/or temperature. The downhole sensors can be individual, discrete sensors distributed or spaced along a length of the barrier and/or a continuous sensor (e.g., fiber optic) located proximate a length of the barrier (e.g., attached to the casing). The sensors can be any of a variety of sensors known to the industry such as electronic sensors (e.g., micro electro-mechanical sensors) or fiber optic sensors. The sensors can periodically report data based on a predetermined reporting interval or reporting frequency. The sensor data can be reported up to the surface through a fiber optic cable, wired cable, acoustics, radio waves, telemetry, or any number of ways known to the industry. The sensor data received at the surface can be stored at the wellsite, stored at a remote location, or transmitted to another location.

The wellbore sensor data gathered at the wellsite can be transmitted to another location for evaluation and storage. The data can be recorded at the wellsite by automated equipment, by service personnel, or both. The data can be periodically gathered and stored on transferrable media, electronic storage, or non-transitory memory at the wellsite. The data from the wellbore sensors can be transmitted to a location remote from the well site through a wired network, wirelessly by satellite, wirelessly by cellular service, or any combination of the foregoing. The data can be stored and transmitted on a predetermined schedule. The data can be stored and transmitted when requested by a computerized application. The data can be gathered and transmitted at a predetermined reporting interval or frequency. The data can be gathered and transmitted when requested by a computerized application.

The transmitted wellbore sensor data can be evaluated by evaluation software executing on a computer to determine a present state of a condition (e.g., stress state) of the barrier (e.g., cement or sealant). The stress state of the well barrier may be modeled from the wellbore data with a finite element analysis (FEA) software. Well barrier evaluation software can utilize temperature, pressure, and stress state condition data from a given well to analyze and report the current state of the barrier and to predict a future state of the barrier. For example, the well barrier evaluation software can utilize FEA modeling to model a future state of the barrier based on a current rate of change of downhole pressure from the decline of production. The well barrier evaluation software can model a future state of the barrier based on a planned well intervention such as a well stimulation. The well barrier evaluation software can model a future state of the barrier based on a planned shutoff of one zone. The well barrier evaluation software can update a user of the current state of the well barrier and its remaining capacity to continue to act as a barrier for hydrocarbons or nonhydrocarbons (CO₂, injected fluids, groundwater, etc.) for a given time interval, including the expected service life of the well.

In some embodiments, the evaluation software can access sensor data stored on a server (e.g., a server located remote from the well site) periodically to evaluate the current state of the well barrier. A user can set the evaluation to be performed periodically such as once an hour, day, week, or month. The user can schedule the evaluation to include a portion of a previously evaluated time period (e.g., overlapping data ranges). For example, the software can evaluate data gathered on Monday, Tuesday, and Wednesday and subsequently evaluate data gathered on Tuesday, Wednesday, and Thursday. The evaluation software can reduce the size of the data set with known mathematical data reduction techniques such as linear regression, logistic regression, and resampling methods. The evaluation software can determine a current stress state then compare the current stress state to a predefined threshold stress value and/or the initial stress state to determine a change in stress state. The evaluation software can alert a user if the current stress state exceeds the threshold stress value and/or if the change in stress state exceeds a change in stress state threshold. The alert from the evaluation software can be any form of communication including email, text message, message within the software, notification on the screen, or any other suitable notification. The evaluation software can send a report to the storage server if the current stress state is below the threshold stress value.

In some embodiments, a user can model a future stress state based on a wellbore servicing procedure such as a well stimulation. A user can send a future applied load or stress (e.g., well stimulation) to the evaluation software to determine a future stress state. The evaluation software can compare the applied stress to the current stress state to determine a future stress state. The software can generate a report showing the future stress state.

Disclosed herein is a method of evaluating a current stress state and future stress state for a cement well barrier. The future stress state can be used to avoid future well operations that would damage the cement well barrier. The future stress state can be used to predict future cement well barrier damage from production rates. The future stress state can be used to alert users of a change to the current stress state of the cement well barrier.

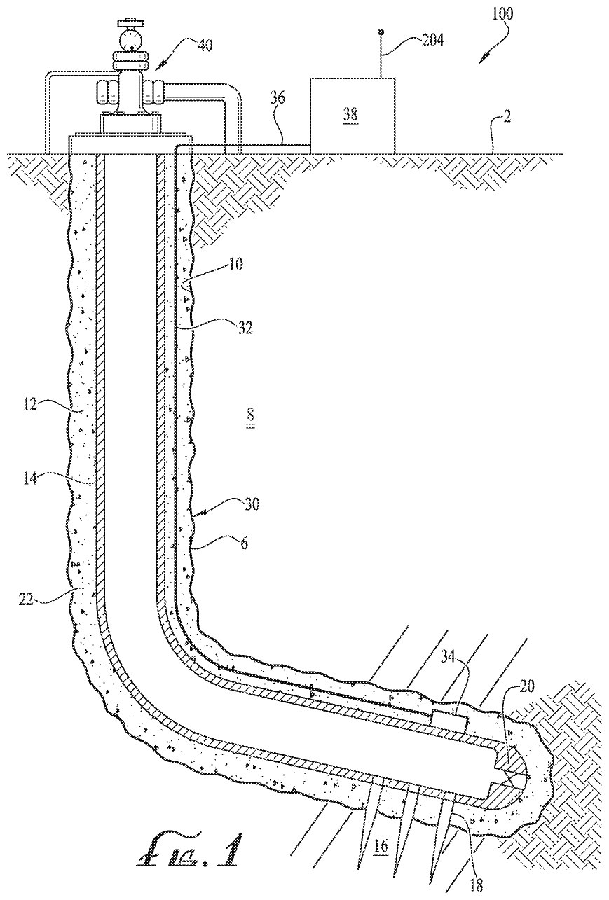

As described in detail herein, a method of monitoring a wellbore is provided wherein one or more downhole sensors present in a wellbore provides data gathered with regard to a stress state of a wellbore isolation barrier. Turning now to FIG. 1, illustrated is an embodiment of a wellbore monitoring system 100 that can be utilized to gather wellbore data. As depicted, the wellbore 10 penetrates a subterranean formation 8 for the purpose of recovering hydrocarbons. The wellbore 10 can be drilled into the subterranean formation 8 using any suitable drilling technique. The wellbore 10 extends substantially vertically away from the earth's surface 2 over a vertical wellbore portion 24, deviates from vertical relative to the earth's surface 2 over a deviated wellbore portion 26, and transitions to a horizontal wellbore portion 28. In alternative operating environments, all or portions of a wellbore may be vertical, deviated at any suitable angle, horizontal, and/or curved. The wellbore 10 may be a new wellbore, an existing wellbore, a straight wellbore, an extended reach wellbore, a sidetracked wellbore, a multi-lateral wellbore, and other types of wellbores for drilling and completing one or more production zones. Further, the wellbore 10 may be used for both producing wells and injection wells. In some embodiments, the wellbore 10 may be used for purposes other than or in addition to hydrocarbon production, such as uses related to geothermal energy.

In some embodiments, the wellbore 10 can be completed by securing a casing string 14 (e.g., a conduit) within the wellbore 10 along all or a portion thereof. The casing string 14 can be secured within the wellbore 10 using a sealant composition suitable to form a barrier between zones within the wellbore. The cement 12 can be pumped down the interior of the casing 14, out a float shoe 20 (or other suitable primary cementing equipment), and into the annular space 22 (e.g., the annulus) between the casing string 14 and the wellbore 10. In other embodiments, however, the casing string 14 may be omitted from all or a portion of the wellbore 10, and the principles of the present disclosure can equally apply to an “open-hole” environment. In still other embodiments, however, the primary cementing equipment 20 at the end of the casing string 14 can be drilled out, and a liner can be added to extend the length of the wellbore.

The cement 12 can be Portland cement or a blend of Portland cement with various additives to tailor the cement for the wellbore environment. For example, retarders or accelerators can be added to the cement slurry to slow down or speed up the curing process. In some embodiments, the cement 12 can be a polymer designed for high temperatures. In some embodiments, the cement 12 can have additives such as expandable elastomer particles.

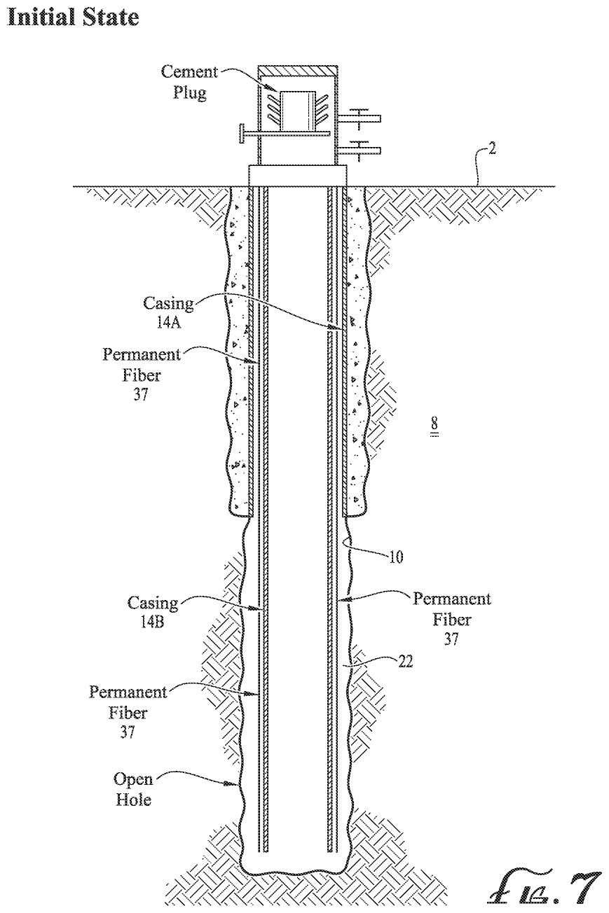

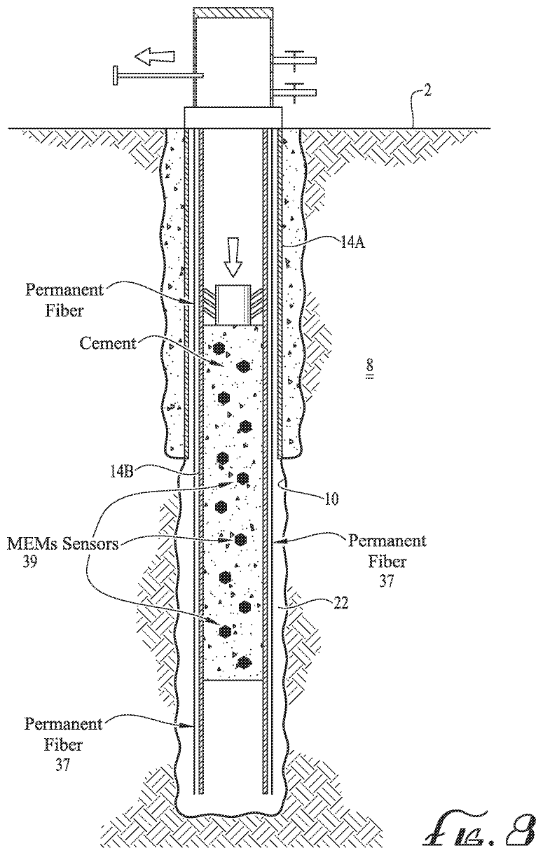

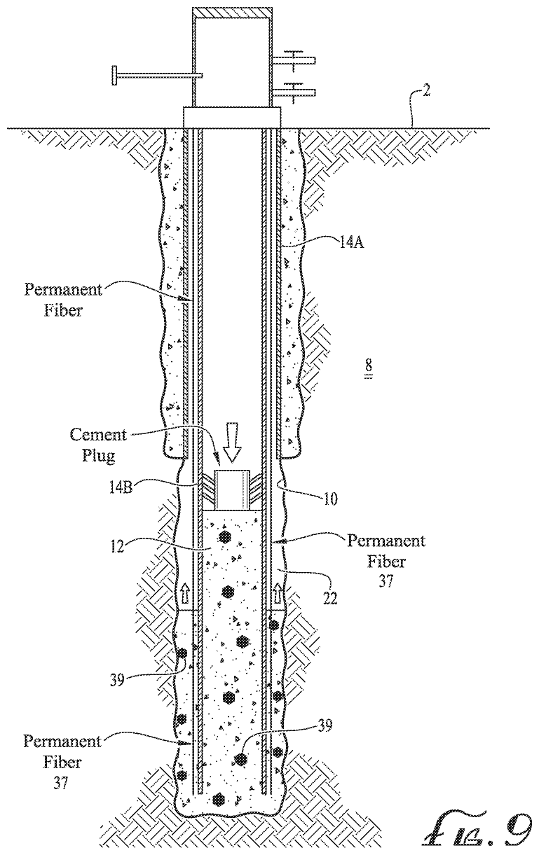

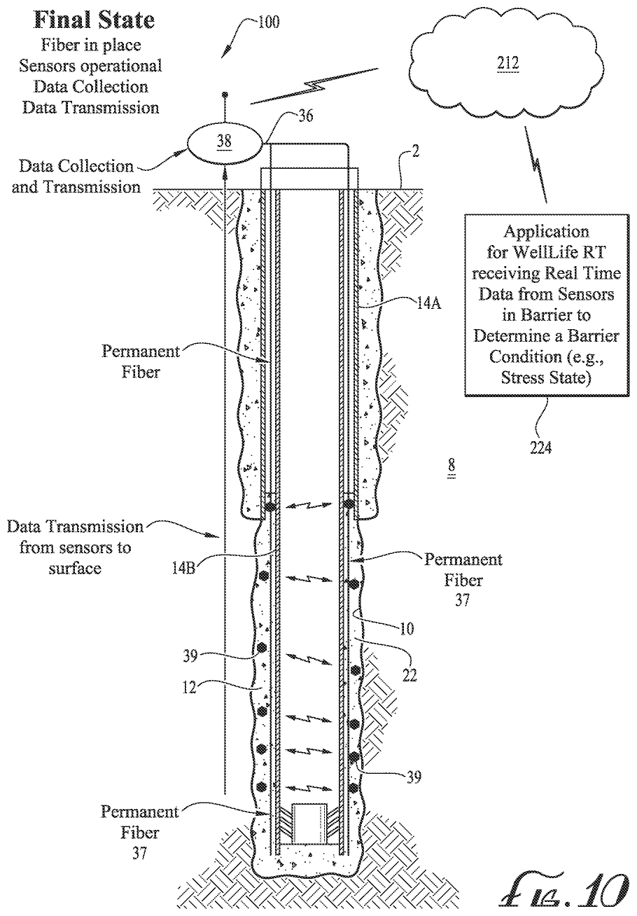

FIGS. 7-10 illustrate a sequence of cementing (e.g., primary cementing) a conduit (e.g., casing) in a wellbore with associated sensor placement. In FIG. 7, a second conduit (e.g., casing or liner 14B) is run into a wellbore having an existing first casing 14A previously disposed and cemented therein. One or more permanent fibers (e.g., fiber optic cables 37) can be secured to the casing 14B during placement thereof in the wellbore. In FIGS. 8 and 9, uncured cement 12 comprising a plurality of MEMS sensors 39 is pumped down through the casing 14B and back up through the annular space 22. In FIG. 10, the cement 12 placed in the annular space 22 between the casing string 14 and the wellbore 10 can cure (harden) to form a wellbore isolation barrier, also referred to as a barrier (e.g., a cement sheath). The term wellbore isolation barrier may refer to a sealant composition (e.g., Portland cement or a blend of Portland cement) that has cured or hardened to form a set barrier composition (e.g., cement sheath) disposed in the annular space.

Any sealant composition compatible with the overall well design and associated geologic conditions of the subterranean formation can be used to form the wellbore isolation barrier. For example, the sealant composition can be a cementitious composition or a non-cementitious composition. In some embodiments, a non-cementitious sealant composition can be a resin or polymeric based sealant composition. For example, the term wellbore isolation barrier can refer to a polymer that has cured or hardened.

The wellbore 10 can be drilled through the subterranean formation 8 to a hydrocarbon bearing formation 16. Perforations 18 in the casing string 14 and cement 12 enable the fluid in the hydrocarbon bearing formation 16 to enter the casing 14.

The cement 12 can have wellbore sensors 30 positioned within the annular space 22 between the casing string 14 and the wellbore 10. The wellbore sensors 30 can include wellbore cables 32, electronic sensors 34, fiber optic sensors 37, and micro electromechanical sensors (MEMS) 39. The wellbore cables 32 can be routed along the outside of the casing 14 and attached at various locations (e.g., at a coupling) with cable clamps known to the industry. The wellbore sensors 30 can be attached to the casing string 14 with a casing clamp, attached to casing equipment, integrated within a sensor housing, or suspended along the casing. In some embodiments, the wellbore sensors 30 can be wellbore cables 32 containing distributed optical sensors such as fiber optic cables 37 shown in FIGS. 7-10. In some embodiments, the wellbore sensors 30 can be electronic sensors 34 with wellbore cables 32 transmitting power and communicating data. In some embodiments, the wellbore sensors 30 can be battery powered electronic sensors 34 transmitting data via sonar, radio, or audio telemetry. In some embodiments, the wellbore sensors 30 can be MEMS 39 as shown in FIGS. 8-10. In some embodiments, the wellbore sensors 30 can be a combination of sensor types, e.g., fiber optic cables 37 and MEMs 39 as shown in FIGS. 7-10. As shown in FIGS. 8-10, the wellbore sensors (e.g., MEMS 39) can be contained within (e.g., distributed within) the cement.

The data gathered by the wellbore sensors 30 can include stress, strain, pressure, temperature, acoustic data, or any combination thereof. The wellbore sensors 30 can measure stress and strain from a strain-bridge (e.g., sensor 34) or a fiber optic cable mounted onto the surface of the casing 14. The wellbore sensors 30 can measure pressure and temperature at a discrete location within the cement isolation barrier. The wellbore sensors 30 may be an optical sensor that can measure a distributed temperature along the optical cable. The wellbore sensors 30 may measure acoustic data from a discrete location of an electronic sensor or along a distributed path of an optical cable. In some embodiments, other properties of the wellbore can be determined or estimated based on the data gathered by the wellbore sensors 20. For example, a flow rate of fluid into or out of the wellbore can be determined based upon data from the wellbore sensors 30 such as temperature data from one or more discrete locations of an electronic sensor or from one or more discrete locations of an optical sensor.

A data logging device 38 can gather data from the wellbore sensors 30 for storage or transmittal. A transmission cable 36 can pass through a production tree 40 attached to the casing string 14 to connect a data logging device 38 to the wellbore cables 32. The data logging device 38 can communicate with the wellbore sensors 30 via any suitable communication means (e.g., wired, wireless, telemetry, etc.). The data can be gathered in data sets based on a time interval. The data set can be retrieved from multiple wellbore sensors 30 instantaneously or near instantaneously and logged with a time stamp. The data sets can be recorded in time intervals of milliseconds, seconds, minutes, hours, days, weeks, or months. The time intervals that the data sets are gathered by the wellbore sensors 30 can change based on the wellbore conditions, user input, or by another application. The data logging device 38 can provide power to and receive data from the wellbore sensors 30. The data logging device 38 can contain an optical interrogator that transmits and receives laser light to the wellbore cables 32 (e.g., fiber optic cables). The data logging device 38 can have a data storage device attached to or integrated within to store the data. The data logging device 38 can store the data in transitory or non-transitory memory, in resident storage media, or in removable storage media. The data logging device 38 can store the data or transmit the data for analysis.

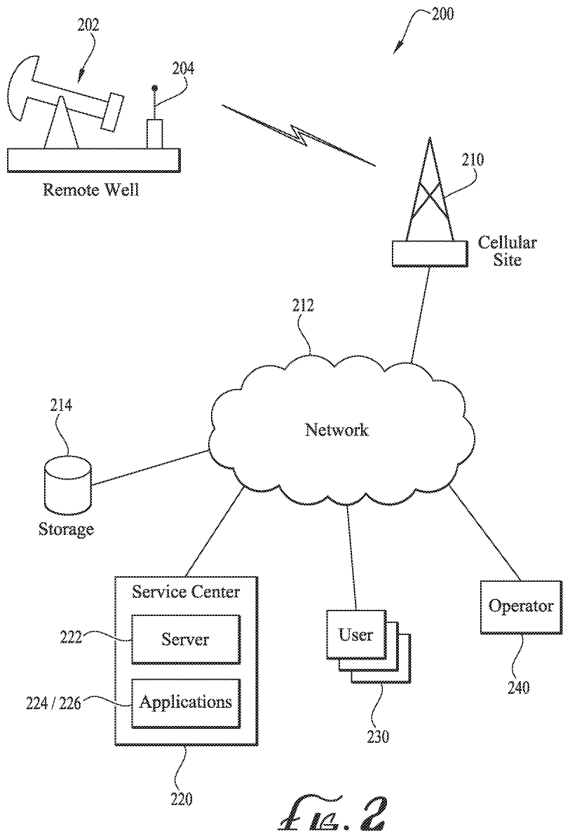

Data having been gathered at the wellsite can be transmitted by various wired or wireless means to a remote location for further processing. Turning now to FIG. 2, a data communication system 200 is described. The data communication system 200 comprises a wellsite 202, a cellular site 210, a network 212, a storage computer or server 214, a central computer or server 222, a plurality of user devices 230, and one or more customer devices 240. A wellsite 202 with a communication device 204 (e.g., associated or integral with data logging device 38 of FIG. 1) can transmit via any suitable communication means (wired or wireless), for example, wirelessly connect to a cellular site 210 to transmit data to a storage server 214. The storage server 214 may also be referred to as a data server, data storage server, or remote server. Wireless communication can include various types of radio communication, including cellular, satellite, or any other form of long-range radio communication. The communication device 204 can transmit data via wired connection for a portion or the entire way to the storage server 214. The communication device 204 may communicate over a combination of wireless and wired communication. For example, communication device 204 may wirelessly connect to cellular site 210 that is communicatively connected to a network 212. The network 212 can be one or more public networks, one or more private networks, or a combination thereof. A portion of the Internet can be included in the network 212. The storage server 214 can be communicatively connected to the network 212. The service center 220 can have one or more central servers 222 communicatively connected to the network 212.

A communication device 204 at a wellsite 202 can transmit one or more data sets collected from the wellbore sensors to a remote storage location according to a predetermined schedule. The remote storage location can be a user device 230, an evaluation application 224, or a storage server 214. In some embodiments, the communication device 204 can communicatively connect to the storage server 214 via the network 212 and/or cellular site 210 based on an established schedule. The established schedule can be set by a user device 230, the evaluation application 224, or a scheduler application 226. The communication device 204 can transmit data based on an event. For example, the communication device 204 can transmit one or more data sets when a number of data sets have been gathered or when the data storage reaches a predetermined amount of capacity (e.g., 25%, 50%, or full).

The user device 230, the evaluation application 224, or the scheduler application 226 can retrieve data from the communication device 204 on the wellsite 202. The retrieved data can be stored locally or in the storage server 214. In some embodiments, the evaluation application 224 can communicatively connect via network 212 and/or the cellular site 210 to the communication device 204 to retrieve one or more data sets. In some embodiments, the user device 230 can retrieve one or more data sets from the communication device 204.

The user device 230 can transfer a data set from the storage server 214 to the evaluation application 224 executing on a server in the service center 220. Alternatively, a data set from the storage server 214 can be transferred automatically or via a scheduler to the evaluation application 224 executing on a server in the service center 220. The data set can include the data collected from wellsite 202 over a designated time period. Using the wellbore data set, the evaluation application 224 can perform a finite element analysis (FEA) from the well design and geometry, geo-mechanical material properties, wellbore environment, and/or loads associated with a wellbore operation (e.g., drilling, casing, cementing, pressure testing, completion, testing, production or injection) to determine one or more conditions of the barrier (e.g., a stress state of the barrier). WellLife® Cement Software available from Halliburton is an example of FEA software suitable for determining a condition of the wellbore barrier such as a stress state of the barrier, a load on the barrier, cracking of the barrier, debonding of the barrier from wall of the well, debonding of the barrier from the conduit, plastic deformation of the barrier, plastic failure of the barrier, extrusion of the barrier, or any combination thereof. In some embodiments, the FEA software accounts for loads associated with a wellbore operation selected from drilling the well, casing the well, cementing the well, pressure testing the well, completing the well, logging the well, injecting fluid into the well, producing fluid from the well, shutting in the well, or any combination thereof for different barrier (e.g., cement) compositions to optimize design of the well. In some embodiments, optimizing the design of the well comprises optimizing one or more of production life of the well, cost of drilling and/or completing the well, cost of maintaining and/or remediating the well over the production life of the well, cost of loss of hydrocarbon (e.g., due to loss of isolation between wellbore zone and resultant interzonal communication, due to water production, etc.), cost of nonproductive time, or any combination thereof.

The finite element method (FEM) is a widely used method for structural analysis utilizing a numerical method of solving partial differential equations in two dimensions or three dimensions. The FEM uses a mesh that reduces a large system (e.g., large volume or large size) into smaller, simpler parts called finite elements. A mesh of points connected with finite elements is generated to overlay the large system (e.g., wellbore). The mesh can vary depending on the parts within the large system. Smaller parts or changes in geometry typically utilize a finer mesh than larger continuous parts. In the example of the wellbore, the evaluation application 224 may place a mesh perpendicular to the axis of the wellbore. The mesh can be finer between the inside diameter and outside diameter of the casing. The mesh can be medium in size between the outside diameter of the casing and the inside surface of the formation. The mesh can be larger in size extending from the inside surface of the formation and radiating outwards. The evaluation application 224 may utilize the material properties of the casing (e.g., mechanical properties of steel) to calculate the stress and strain. The evaluation application 224 may utilize the material properties of the cement mixture pumped into the well. The evaluation application 224 may base the mechanical strength of the cement on the laboratory testing results of the cement at well environmental conditions to determine the stress state of the cement. The evaluation application 224 may utilize the geo-mechanical properties of the formation to evaluate the stress within the formation.

The evaluation application 224 can determine a stress state of the isolation barrier at a location for the time period selected. In some embodiments, the evaluation application 224 determines a stress state of the isolation barrier as it existing before, during, and/or after a wellbore operation such as drilling, casing, cementing, pressure testing, completion, testing, production or injection (for example, as shown in FIG. 11). The evaluation application 224 can apply a mesh perpendicular to the axis of the wellbore and at a location selected by the user. The location can be a single cross-sectional area of the wellbore perpendicular to the axis of the wellbore or an extended range from one location to a second location. The evaluation application 224 can determine the stress state within a single zone of a multiple zone well. For example, the first zone can extend from the bottom of the well (e.g., total depth of the well), also called the shoe depth of the well, to a geological formation that can be 1000 feet from the shoe. The casing can be perforated in one or more locations within the first zone. The evaluation application may apply a mesh from the shoe of the well up to the geological formation. The evaluation application 224 can evaluate a stress state of the cement barrier between the casing and the formation within the first zone. The user device 230 can transmit a report generated by the evaluation application 224 to the operator via network 212.

A user may establish a stress value threshold to compare with the modeled stress state. The stress value threshold can be selected based on a failure mode of the casing, the isolation barrier, the formation rock, or any combination thereof. The casing, isolation barrier, and formation can be subjected to a combined loading from any combination of pressure inside the casing, formation pressure, the casing in tension, and the casing in compression. The combined loading may apply stress to the isolation barrier. For example, a high internal pressure and a low formation pressure, also referred to as burst pressure, may cause a pressure differential that can burst the casing, crack the isolation barrier, and apply a compression load on the formation. A burst pressure may also place the casing and cement in tension if the end of the casing is plugged resulting in elongation of the casing. The stress value threshold can be determined by laboratory testing of the isolation barrier to determine the material strength in response to stress and strain. For example, the isolation barrier may be susceptible to shear in response to compressive stress. The stress value threshold can be selected to prevent a failure of the isolation barrier.

The evaluation application 224 can predict a future stress state based on two or more modeled stress states. The current stress state can be compared to a previous stress state to predict a future stress state. For example, the rate of change can be determined by comparing one or more previous stress states to the current stress state. The evaluation application 224 can employ one or more numerical methods to predict a future stress state based on the rate of change of the isolation barrier stress states. The future stress state can be compared to a user threshold to determine if a preventative and/or remedial action is recommended. Examples of preventative actions include modifying an operational parameter of the well (e.g., flow rate of fluid in or out of the well (change production rate), length/duration/frequency of shutdown intervals for the well); modifying a maintenance schedule of the well; modifying a construction parameter of a future well; modifying a completion parameter of a future well; or any combination thereof. Examples of remedial actions include a squeeze operation (e.g., squeeze cement or squeeze sealant) to place a remedial barrier composition in a location of compromised integrity of the barrier in the well; plugging a portion of the well; fracturing a portion of the well; acidizing a portion of the well; recompleting all or a portion of the well; sidetracking the well and newly completing the sidetracked portion; or any combination thereof.

The evaluation application 224 can project a future stress state based on an applied stress state. An applied stress can be loads applied to the barrier during a wellbore servicing operation requested by a production company. Some examples of an applied stress can include loads associated with plugging the wellbore with a service tool, closing off a zone of production, pumping a treatment into a production zone, or shutting off production from a producing well. For example, pumping a treatment into a production zone can cause a tensile stress in the casing from cooling of the wellbore, and ballooning of the casing and isolation barrier from applied pressure inside the casing. The evaluation application 224 can model a future stress state based on the current modeled stress state and an applied stress state. The future stress state can be compared to a user threshold to determine if the wellbore servicing operation is recommended (e.g., a preventative and/or remedial action).

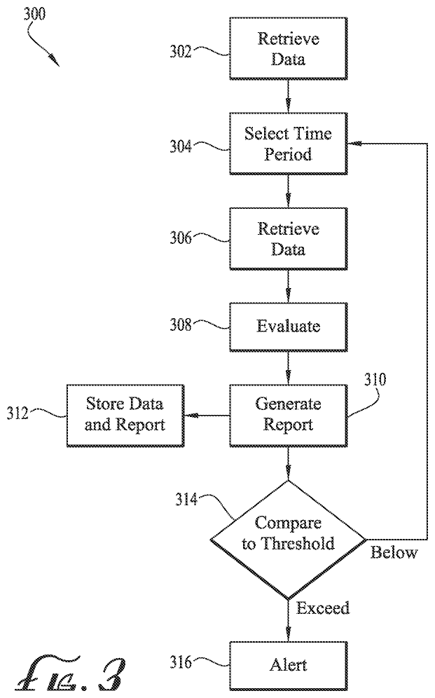

Turning now to FIG. 3 with reference to FIG. 2, a method 300 of evaluating a stress state is illustrated as a logic block diagram. The method 300 of evaluating a stress state of a wellbore isolation barrier with an evaluation application comprises the following steps. At block 302, the evaluation application can retrieve a plurality of data sets from the remote storage of communication device 204 on the wellsite 202. The evaluation application 224 executing on a server in the service center 220 can establish a communication method, e.g., a wired or wireless connection such as wireless connection between the communication device 204 and the cellular site 210 via the network 212. In some embodiments, the communication device 204 can be communicatively connected to the network 212. In some embodiments, the communication device 204 can connect to the network 212 via a wireless link to a satellite and a wireless link to a satellite receiver. In some embodiments, the communication device 204 can be located on a server communicatively connected to the network 212. In some embodiments, the communication device 204 can be a data storage device that is transported to a user device 230.

The data sets can be data received from wellbore sensors 30, as discussed in FIG. 1, the sensors can be located proximate (e.g., inside or affixed on an exterior surface of) the wellbore barrier and record pressure, temperature, stress, strain, acoustics, or any combination thereof. The data sets can be recorded in time intervals of milliseconds, seconds, minutes, hours, days, weeks, or months. The time intervals that the data sets are gathered by the wellbore sensors 30 can change based on the wellbore conditions. The data sets can be saved onto the storage server 214.

At block 304, a user can select a data set from the storage server 214, for example a data set corresponding to a particular time period (e.g., data from the previous 6 months). The data set can comprise the data set received from the communication device 204.

At block 306, the evaluation application 224 can retrieve a data set from the storage server 214.

At block 308, the evaluation application 224 can determine a modeled stress state of the wellbore isolation barrier from the data set retrieved from the storage server 214. The evaluation application 224 can utilize a Finite Element Analysis (FEA) technique to model the stress state within the wellbore isolation barrier. In some embodiments, the evaluation application 224 includes barrier evaluation/modeling software such as WellLife® Cement Software available from Halliburton, which can include FEA analysis of the barrier (e.g., cement).

At block 310, the evaluation application 224 can generate a report detailing the stress state analysis of the wellbore isolation barrier. At block 312, the received data set and the report can be saved to a storage server 214.

At block 314, the evaluation application 224 can compare the modeled stress state to a user defined stress value threshold (e.g., a stress value threshold designated by a user). The evaluation application 224 can return to block 304 to evaluate a second time interval if the modeled stress state is below a user defined stress value threshold.

The evaluation application 224 can step to block 316 and alert the user if the modeled stress state is above a user defined stress value threshold.

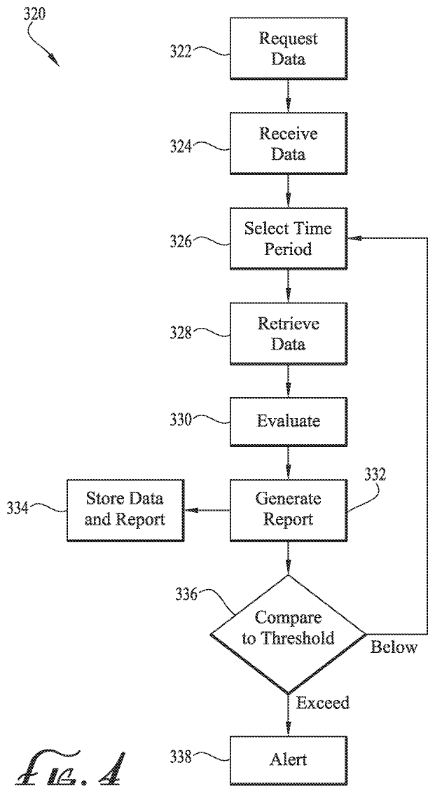

Turning now to FIG. 4, a method 320 of evaluating a stress state of a wellbore isolation barrier with an evaluation application is illustrated as a logic block diagram. The method 320 comprises the following steps executing in an evaluation application. At block 322, the evaluation application 224, as shown in FIG. 2, can request a plurality of data sets from the remote storage of communication device 204 on the wellsite 202. The evaluation application 224 executing on a server in the service center 220 can establish a wireless connection between the communication device 204 and the cellular site 210 via the network 212. The data sets can be the remote storage or can be scheduled to be gathered. The evaluation application 224 can schedule a data set to be gathered over a time interval.

At block 324, the communication device 204 on the wellsite 202 can communicatively connect to the evaluation application 224 via the cellular site 210 and network 212. The communication device 204 can transmit a plurality of data sets from the remote storage to the evaluation application 224. The evaluation application can save them to storage server 214.

At block 326, a user can select a data set from the storage server 214, for example a data set corresponding to a period of time such as the previous 6 months. The data set can comprise the data set received from the communication device 204. At block 328, the evaluation application 224 can retrieve a data set from the storage server 214.

At block 330, the evaluation application 224 can determine a modeled stress state of the wellbore isolation barrier from the data set retrieved from the storage server 214. The evaluation application can utilize a Finite Element Analysis (FEA) technique to model the stress state within the wellbore isolation barrier. In some embodiments, the evaluation application includes barrier evaluation/modeling software such as WellLife® Cement Software available from Halliburton, which can include FEA analysis of the barrier (e.g., cement).

At block 332, the evaluation application 224 can generate a report detailing the stress state analysis of the wellbore isolation barrier. At block 334, the received data set and the report can be saved to a storage server 214.

At block 336, the evaluation application 224 can compare the modeled stress state to a user threshold (e.g., a stress threshold designated by a user). The evaluation application 224 can return to block 326 to evaluate a second time interval if the modeled stress state is below a user threshold. The evaluation application 224 can step to block 338 and alert the user if the modeled stress state is above a user threshold.

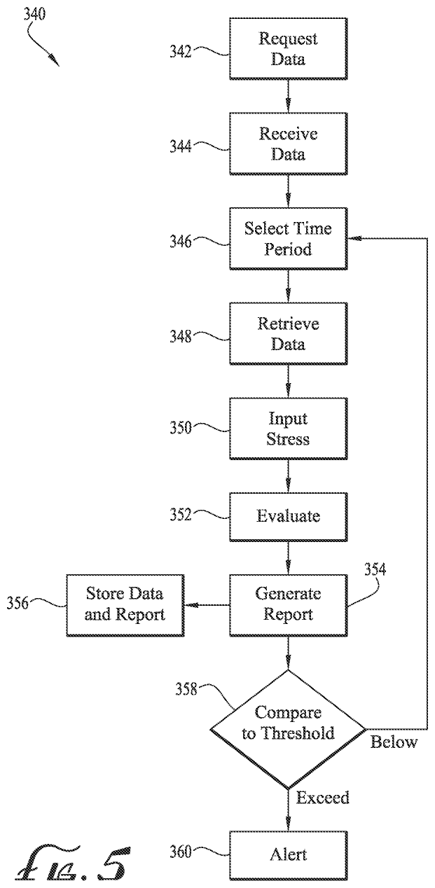

Turning now to FIG. 5, a method 340 of evaluating a stress state of a wellbore isolation barrier with an evaluation application is illustrated as a logic block diagram. The method 340 comprises the following steps executing in an evaluation application. At block 342, the evaluation application 224, as shown in FIG. 2, can request a plurality of data sets from the remote storage of communication device 204 on the wellsite 202. The evaluation application 224 executing on a server in the service center 220 can establish a wireless connection between the communication device 204 and the cellular site 210 via the network 212. The data sets can be the remote storage or can be scheduled to be gathered. The evaluation application 224 can schedule a data set to be gathered over a time interval.

At block 344, the communication device 204 on the wellsite 202 can communicatively connect to the evaluation application 224 via the cellular site 210 and network 212. The communication device 204 can transmit a plurality of data sets from the remote storage to the evaluation application 224. The evaluation application can save them to storage server 214.

At block 346, a user can select a data set from the storage server 214, for example a data set corresponding to a period of time such as the previous 6 months. The data set can comprise the data set received from the communication device 204.

At block 348, the evaluation application 224 can retrieve a data set from the storage server 214.

At block 350, a future stress event can be input into the evaluation application 224, for example by user device 230. Examples of future stress events include well interventions or servicing operations such as fracturing jobs, pressure tests, changes in production, shut-ins, etc.

At block 352, the evaluation application 224 can determine a future stress state of the wellbore isolation barrier from the data set retrieved from the storage server 214 and the future stress event. The evaluation application can utilize a Finite Element Analysis (FEA) technique to model the future stress state within the wellbore isolation barrier taking into account the future stress event. In some embodiments, the evaluation application includes barrier evaluation/modeling software such as WellLife® Cement Software available from Halliburton, which can include FEA analysis of the barrier (e.g., cement).

At block 354, the evaluation application 224 can generate a report detailing the future state analysis of the wellbore isolation barrier. At block 356, the received data set and the report can be saved to a storage server 214.

At block 358, the evaluation application 224 can compare the future stress state to a user threshold (e.g., a stress threshold designated by a user). The evaluation application 224 can return to block 346 to evaluate a second time interval if the future stress state is below a user threshold. The evaluation application 224 can step to block 360 and alert the user if the future stress state is above a user threshold.

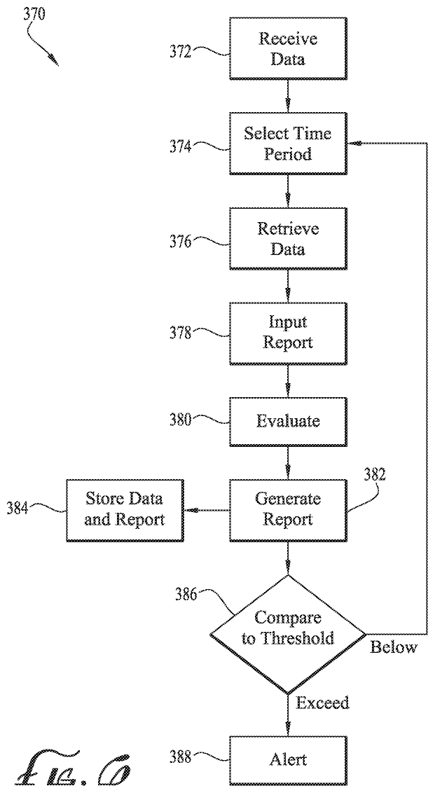

Turning now to FIG. 6, a method 370 of evaluating a stress state of a wellbore isolation barrier with an evaluation application is illustrated as a logic block diagram. The method 370 comprises the following steps executing in an evaluation application. At block 372, the evaluation application 224, as shown in FIG. 2, receives a plurality of data sets from the remote storage of communication device 204 on the wellsite 202. The evaluation application 224 executing on a server in the service center 220 can establish a wireless connection between the communication device 204 and the cellular site 210 via the network 212. The data sets can be the remote storage or can be scheduled to be gathered. The evaluation application 224 can schedule a data set to be gathered over a time interval. The communication device 204 on the wellsite 202 can communicatively connect to the evaluation application 224 via the cellular site 210 and network 212. The communication device 204 can transmit a plurality of data sets from the remote storage to the evaluation application 224. The evaluation application can save them to storage server 214.

At block 374, a user can select a data set from the storage server 214, for example a data set corresponding to a period of time such as the previous 6 months. The data set can comprise the data set received from the communication device 204.

At block 376, the evaluation application 224 can retrieve a data set from the storage server 214.

At block 378, one or more previous/past stress states of the wellbore isolation barrier can be retrieved from storage server 214 and/or can be input into the evaluation application 224, for example by user device 230. For example, a current or present stress state determined from a data set corresponding to the past six months (i.e., 1 to 6 months ago) can be compared to a past/previous stress state that has been (or presently is) determined for a preceding another 6 months (e.g., 7 to 12 months ago).

At block 380, the evaluation application 224 can determine a future stress state of the wellbore isolation barrier by comparing the current stress state to one or more previous/past stress states. The evaluation application can utilize a Finite Element Analysis (FEA) technique to model the future stress state within the wellbore isolation barrier taking into account the current stress state in comparison to a previous/past stress state. In some embodiments, the evaluation application includes barrier evaluation/modeling software such as WellLife® Cement Software available from Halliburton, which can include FEA analysis of the barrier (e.g., cement).

At block 382, the evaluation application 224 can generate a report detailing the future state analysis of the wellbore isolation barrier. At block 384, the received data set and the report can be saved to a storage server 214.

At block 386, the evaluation application 224 can compare the future stress state to a user threshold (e.g., a stress threshold designated by a user). The evaluation application 224 can return to block 374 to evaluate a second time interval if the future stress state is below a user threshold.

The evaluation application 224 can step to block 388 and alert the user if the future stress state is above a user threshold.

### Example

This Example relates to the use of a Finite Elemental Analysis (FEA) model to gather real time temperature, pressure and stress state conditions in the barrier through sensors either encased in the barrier itself as individual sensors and/or sensors that are affixed to the outside of the casing.

The long-term efficacy of a well barrier (e.g., a zonal isolation composition) has long been an area that is determined at the time of well construction. Barriers placed in a wellbore (whether they are Portland cement or non-Portland barriers) change over time due to many factors such as changes in production, temperature, pressure, depletion of the reservoir and for the many instances where interventions may be carried out during the life of a well. The ability to determine problems with a well barrier can be costly and potentially damaging to the well to carry out these evaluations throughout the life of a well. Early detection of barrier failures can help an operator or well owner diagnose the cause of the barrier failure and potentially allow changes that would prolong the life of the well.

The product proposed would be the use of an FEA model to be able to gather real time temperature, pressure and stress state conditions in the barrier through sensors either encased in the barrier itself as individual sensors or sensors that are affixed to the outside of the casing, as shown in FIGS. 7-10. These sensors could be provided through a smart completion or independent sensors affixed or suspended in the barrier materials (e.g., cement or sealant) as shown in FIGS. 8-10. These sensors would communicate their state (Temp, Press and Stress/Strain state) up to the surface of the well via radio, acoustic, fiber or through a wired telemetry to be transmitted from the well location to be able to be parsed for updates into a barrier evaluation software such as WellLife® Cement Software, to continually update the user of the software, the state of the barrier and its remaining capacity to continue to act as a barrier for hydrocarbons or nonhydrocarbons (CO₂, injected fluids, ground water etc.) for the life of the well. In addition, the modeling can be used to understand the changing state of the barrier to forecast the potential loads, compare incoming data to the “planned” loads from original WellLife® Cement Software modelling, and then extend them. This would allow the operator of the well to identify operational regimes that are damaging, and make suggestions such as reducing draw down during production, shorten warmback/shut ins (etc.) to prevent damage from occurring to the primary barrier.

Improvements would include converting current well evaluation software through Finite Elemental Analysis of barrier products in a wellbore to be updated and calculated on a regular basis to inform the user of any changes to the barrier through the life of the well. This could be done at different levels. A new technique is proposed to aggregate the data from the wellbore and evaluate the data automatically, for example as depicted with reference to Levels 1-3 below.

Level 1—Data is aggregated into an input file and sent to the user to update program manually, use then updates client of change to barrier state.

Level 2—Data is aggregated into an input file and the program is run automatically in a pre-specified time period. Output data informs user and client of change to barrier state.

Level 3—Data is aggregated into an input file and compared to previous data determining the need to be run based on the inputs and is run automatically. Output data informs user and client of change to barrier state.

With reference to FIGS. 7-10, sensors placed in a wellbore annulus of a liner or casing can transmit information from the sensor (pressure, temperature, stress, strain, flow) to a fiber for the purpose of transmitting that data to surface to then be relayed to the cloud or directly to a computer setup for the purpose of monitoring a cement sheath and the stress state of said cement sheath to indicate to the end user the viability and/or the remaining capacity of the cement sheath. This is depicted in FIG. 10 with a fiber, however other telemetry can be used to source the data from the sensors and communicate it to surface. This can be done via radio waves, acoustic waves, or other means. The data can then be transmitted as shown here directly to the cloud or via other means to bring the real time data to a computing device that is running the WellLife® Cement Software which will evaluate the cement sheath at different times over the life of the well (e.g., in response to various loads being applied to the barrier over the life of the well).

Referring to FIG. 11, a schematic diagram is shown representing the sequencing of loads associated with events that occur during the life of a well. Formation event state 1, casing event state 2, and cement event state 3 correspond to the sequence of events shown in FIGS. 1 and 7-10 (e.g., primary cementing of a wellbore) as shown herein. Upon completion of primary cementing, the well may undergo curing, pressure testing, completion, and shut-in, which can be referred to as an initial or baseline event state 4, wherein the well is completed and ready to being service (e.g., ready to begin commercial production of hydrocarbons). With downhole sensors in place as described herein, an initial or baseline stress state can be determined associated with event state 4 (e.g., the beginning of commercial well operation that is post-completion and pre-commercial production). Data can be gathered from the downhole sensors and (i) an initial stress state of the barrier can be determined immediately using FEA software (e.g., WellLife® Cement Software), (2) predicted, future stress states associated with target production operations can be determined immediately, and (iii) then an operator can track and compare actual real time production operation (e.g., effects to the barrier (e.g., cement sheath) associated with event state 5 of FIG. 11) vs. predicted stress state calculations to determine if preventative and/or remedial actions are needed. In other words, once the sensors are present and monitoring parameters of cement barrier in real time, a well operator would compare and update our calculated conditions at event state 4 (e.g., an initial stress state), and then use that updated stress state determined at event state 4 (e.g., an initial stress state) as a starting point for the forthcoming commercial production operations. Likewise, an operator could further calculate and compare future barrier stress states associated with future events such as fracturing event 7, evacuation event 8, or any other user defined sequence of load events.

WellLife® Cement Software available from Halliburton that can simulate operations such as drilling, casing, cementing, pressure testing, completion, testing, and/or fluid flow (e.g., production from or injection into the well) for different cement systems to optimize well design. WellLife® Cement Software can be used to simulate complex wellbore geometries such as multiple overlapping casings, fish hook wells, tieback casings, and liners. WellLife® Cement Software can be used to determine, inter alia, shear failure during drilling; eccentricity and/or plastic failure during running of casing; initial shear state, heat of hydration, and/or shrinkage/expansion during cementing operations; wellbore parameters (e.g., load on a barrier such as a cement sheath) during curing, pressure testing, completion, shut-in, production, injection, fracturing, evacuation, or any combination thereof. The present application provides methods and systems for continuous, active, automatic, and/or real-time monitoring of one or more wellbore parameters (e.g., pressure, temperature, stress, strain) related to a condition of a barrier in the wellbore (e.g., stress state), which can be performed from a location remote from the well itself, for a lifetime of the well. The present application provides for enhanced well life (e.g., maintain effective commercial operation of the well for its predetermined life or longer), reduced maintenance, enhanced productivity, predictive maintenance and the like over present methods and systems of monitoring a well.

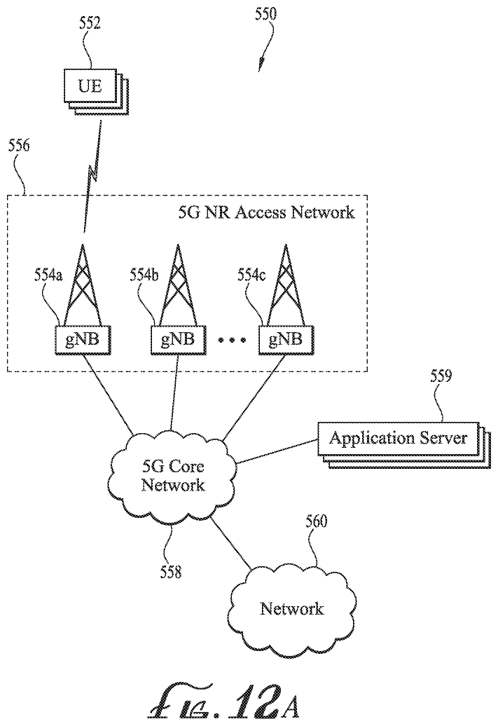

Turning now to FIG. 12A, an exemplary communication system 550 is described. In an aspect, communication system 550 is used to implement communications as described herein, for example without limitation communication system 550 may be used to implement all or a portion of data communication system 200 of FIG. 2 (e.g., network 212 of FIG. 2 can correspond to network 558 and/or 560 of FIGS. 12A and 12B; server 222 of FIG. 2 can correspond to server 559 of FIG. 12A; a communication device 204 of FIG. 2 can correspond with a UE 552 of FIG. 12A; etc.). Typically the communication system 550 includes a number of access nodes 554 that are configured to provide coverage in which UEs 552 such as cell phones, tablet computers, machine-type-communication devices, tracking devices, embedded wireless modules, and/or other wirelessly equipped communication devices (whether or not user operated), can operate. The access nodes 554 may be said to establish an access network 556. The access network 556 may be referred to as a radio access network (RAN) in some contexts. In a 5G technology generation an access node 554 may be referred to as a gigabit Node B (gNB). In 4G technology (e.g., long term evolution (LTE) technology) an access node 554 may be referred to as an enhanced Node B (eNB). In 3G technology (.e.g., code division multiple access (CDMA) and global system for mobile communication (GSM)) an access node 554 may be referred to as a base transceiver station (BTS) combined with a basic station controller (BSC). In some contexts, the access node 554 may be referred to as a cell site or a cell tower. In some implementations, a picocell may provide some of the functionality of an access node 554, albeit with a constrained coverage area. Each of these different embodiments of an access node 554 may be considered to provide roughly similar functions in the different technology generations.

In an embodiment, the access network 556 comprises a first access node 554a, a second access node 554b, and a third access node 554c. It is understood that the access network 556 may include any number of access nodes 554. Further, each access node 554 could be coupled with a core network 558 that provides connectivity with various application servers 559 and/or a network 560. In an embodiment, at least some of the application servers 559 may be located close to the network edge (e.g., geographically close to the UE 552 and the end user) to deliver so-called “edge computing.” The network 560 may be one or more private networks, one or more public networks, or a combination thereof. The network 560 may comprise the public switched telephone network (PSTN). The network 560 may comprise the Internet. With this arrangement, a UE 552 within coverage of the access network 556 could engage in air-interface communication with an access node 554 and could thereby communicate via the access node 554 with various application servers and other entities.

The communication system 550 could operate in accordance with a particular radio access technology (RAT), with communications from an access node 554 to UEs 552 defining a downlink or forward link and communications from the UEs 552 to the access node 554 defining an uplink or reverse link. Over the years, the industry has developed various generations of RATs, in a continuous effort to increase available data rate and quality of service for end users. These generations have ranged from “1G,” which used simple analog frequency modulation to facilitate basic voice-call service, to “4G”—such as Long Term Evolution (LTE), which now facilitates mobile broadband service using technologies such as orthogonal frequency division multiplexing (OFDM) and multiple input multiple output (MIMO).

Recently, the industry has been exploring developments in “5G” and particularly “5G NR” (5G New Radio), which may use a scalable OFDM air interface, advanced channel coding, massive MIMO, beamforming, mobile mmWave (e.g., frequency bands above 24 GHz), and/or other features, to support higher data rates and countless applications, such as mission-critical services, enhanced mobile broadband, and massive Internet of Things (IoT). 5G is hoped to provide virtually unlimited bandwidth on demand, for example providing access on demand to as much as 20 gigabits per second (Gbps) downlink data throughput and as much as 10 Gbps uplink data throughput. Due to the increased bandwidth associated with 5G, it is expected that the new networks will serve, in addition to conventional cell phones, general internet service providers for laptops and desktop computers, competing with existing ISPs such as cable internet, and also will make possible new applications in internet of things (IoT) and machine to machine areas.

In accordance with the RAT, each access node 554 could provide service on one or more radio-frequency (RF) carriers, each of which could be frequency division duplex (FDD), with separate frequency channels for downlink and uplink communication, or time division duplex (TDD), with a single frequency channel multiplexed over time between downlink and uplink use. Each such frequency channel could be defined as a specific range of frequency (e.g., in radio-frequency (RF) spectrum) having a bandwidth and a center frequency and thus extending from a low-end frequency to a high-end frequency. Further, on the downlink and uplink channels, the coverage of each access node 554 could define an air interface configured in a specific manner to define physical resources for carrying information wirelessly between the access node 554 and UEs 552.

Without limitation, for instance, the air interface could be divided over time into frames, subframes, and symbol time segments, and over frequency into subcarriers that could be modulated to carry data. The example air interface could thus define an array of time-frequency resource elements each being at a respective symbol time segment and subcarrier, and the subcarrier of each resource element could be modulated to carry data. Further, in each subframe or other transmission time interval (TTI), the resource elements on the downlink and uplink could be grouped to define physical resource blocks (PRBs) that the access node could allocate as needed to carry data between the access node and served UEs 552.

In addition, certain resource elements on the example air interface could be reserved for special purposes. For instance, on the downlink, certain resource elements could be reserved to carry synchronization signals that UEs 552 could detect as an indication of the presence of coverage and to establish frame timing, other resource elements could be reserved to carry a reference signal that UEs 552 could measure in order to determine coverage strength, and still other resource elements could be reserved to carry other control signaling such as PRB-scheduling directives and acknowledgement messaging from the access node 554 to served UEs 552. And on the uplink, certain resource elements could be reserved to carry random access signaling from UEs 552 to the access node 554, and other resource elements could be reserved to carry other control signaling such as PRB-scheduling requests and acknowledgement signaling from UEs 552 to the access node 554

The access node 554, in some instances, may be split functionally into a radio unit (RU), a distributed unit (DU), and a central unit (CU) where each of the RU, DU, and CU have distinctive roles to play in the access network 556. The RU provides radio functions. The DU provides L1 and L2 real-time scheduling functions; and the CU provides higher L2 and L3 non-real time scheduling. This split supports flexibility in deploying the DU and CU. The CU may be hosted in a regional cloud data center. The DU may be co-located with the RU, or the DU may be hosted in an edge cloud data center.

Turning now to FIG. 12B, further details of the core network 558 are described. In an embodiment, the core network 558 is a 5G core network. 5G core network technology is based on a service-based architecture paradigm. Rather than constructing the 5G core network as a series of special purpose communication nodes (e.g., an HSS node, a MME node, etc.) running on dedicated server computers, the 5G core network is provided as a set of services or network functions. These services or network functions can be executed on virtual servers in a cloud computing environment which supports dynamic scaling and avoidance of long-term capital expenditures (fees for use may substitute for capital expenditures). These network functions can include, for example, a user plane function (UPF) 579, an authentication server function (AUSF) 575, an access and mobility management function (AMF) 576, a session management function (SMF) 577, a network exposure function (NEF) 570, a network repository function (NRF) 571, a policy control function (PCF) 572, a unified data management (UDM) 573, a network slice selection function (NSSF) 574, and other network functions. The network functions may be referred to as virtual network functions (VNFs) in some contexts.

Network functions may be formed by a combination of small pieces of software called microservices. Some microservices can be re-used in composing different network functions, thereby leveraging the utility of such microservices. Network functions may offer services to other network functions by extending application programming interfaces (APIs) to those other network functions that call their services via the APIs. The 5G core network 558 may be segregated into a user plane 580 and a control plane 582, thereby promoting independent scalability, evolution, and flexible deployment.

The UPF 579 delivers packet processing and links the UE 552, via the access node 556, to a data network 590 (e.g., the network 560 illustrated in FIG. 6A). The AMF 576 handles registration and connection management of non-access stratum (NAS) signaling with the UE 552. Said in other words, the AMF 576 manages UE registration and mobility issues. The AMF 576 manages reachability of the UEs 552 as well as various security issues. The SMF 577 handles session management issues. Specifically, the SMF 577 creates, updates, and removes (destroys) protocol data unit (PDU) sessions and manages the session context within the UPF 579. The SMF 577 decouples other control plane functions from user plane functions by performing dynamic host configuration protocol (DHCP) functions and IP address management functions. The AUSF 575 facilitates security processes.

The NEF 570 securely exposes the services and capabilities provided by network functions. The NRF 571 supports service registration by network functions and discovery of network functions by other network functions. The PCF 572 supports policy control decisions and flow-based charging control. The UDM 573 manages network user data and can be paired with a user data repository (UDR) that stores user data such as customer profile information, customer authentication number, and encryption keys for the information. An application function 592, which may be located outside of the core network 558, exposes the application layer for interacting with the core network 558. In an embodiment, the application function 592 may be execute on an application server 559 located geographically proximate to the UE 552 in an “edge computing” deployment mode. The core network 558 can provide a network slice to a subscriber, for example an enterprise customer, that is composed of a plurality of 5G network functions that are configured to provide customized communication service for that subscriber, for example to provide communication service in accordance with communication policies defined by the customer. The NSSF 574 can help the AMF 576 to select the network slice instance (NSI) for use with the UE 552.

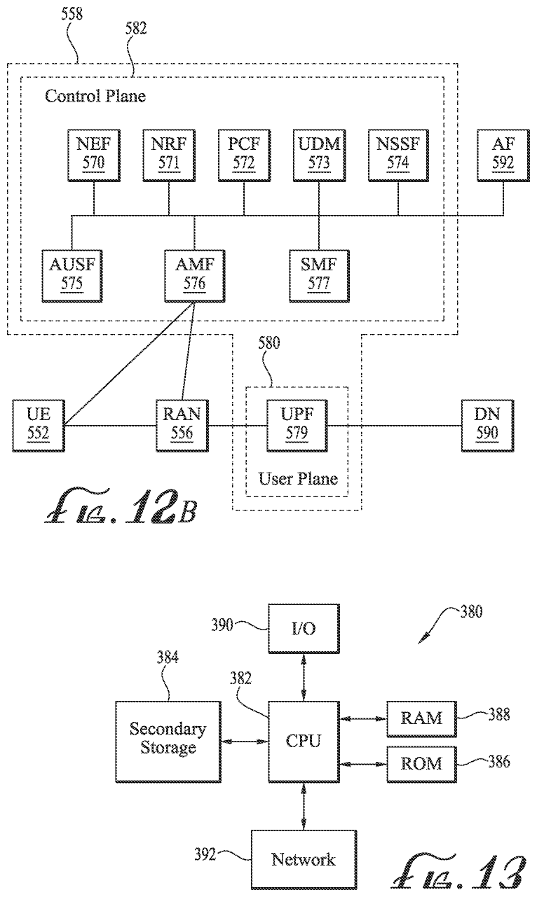

FIG. 13 illustrates a computer system 380 suitable for implementing one or more computer or server embodiments disclosed herein, for example without limitation computer system 380 of FIG. 13 may be used to implement all or a portion of computer or servers 214 and 222 of FIG. 2, a computer or server used by user 230 or operator 240 of FIG. 2, or data logging device 38 of FIGS. 1 and 10. The computer system 380 includes a processor 382 (which may be referred to as a central processor unit or CPU) that is in communication with memory devices including secondary storage 384, read only memory (ROM) 386, random access memory (RAM) 388, input/output (I/O) devices 390, and network connectivity devices 392. The processor 382 may be implemented as one or more CPU chips.

It is understood that by programming and/or loading executable instructions onto the computer system 380, at least one of the CPU 382, the RAM 388, and the ROM 386 are changed, transforming the computer system 380 in part into a particular machine or apparatus having the novel functionality taught by the present disclosure. It is fundamental to the electrical engineering and software engineering arts that functionality that can be implemented by loading executable software into a computer can be converted to a hardware implementation by well-known design rules. Decisions between implementing a concept in software versus hardware typically hinge on considerations of stability of the design and numbers of units to be produced rather than any issues involved in translating from the software domain to the hardware domain. Generally, a design that is still subject to frequent change may be preferred to be implemented in software, because re-spinning a hardware implementation is more expensive than re-spinning a software design. Generally, a design that is stable that will be produced in large volume may be preferred to be implemented in hardware, for example in an application specific integrated circuit (ASIC), because for large production runs the hardware implementation may be less expensive than the software implementation. Often a design may be developed and tested in a software form and later transformed, by well-known design rules, to an equivalent hardware implementation in an application specific integrated circuit that hardwires the instructions of the software. In the same manner as a machine controlled by a new ASIC is a particular machine or apparatus, likewise a computer that has been programmed and/or loaded with executable instructions may be viewed as a particular machine or apparatus.

Additionally, after the system 380 is turned on or booted, the CPU 382 may execute a computer program or application. For example, the CPU 382 may execute software or firmware stored in the ROM 386 or stored in the RAM 388. In some cases, on boot and/or when the application is initiated, the CPU 382 may copy the application or portions of the application from the secondary storage 384 to the RAM 388 or to memory space within the CPU 382 itself, and the CPU 382 may then execute instructions that the application is comprised of In some cases, the CPU 382 may copy the application or portions of the application from memory accessed via the network connectivity devices 392 or via the I/O devices 390 to the RAM 388 or to memory space within the CPU 382, and the CPU 382 may then execute instructions that the application is comprised of During execution, an application may load instructions into the CPU 382, for example load some of the instructions of the application into a cache of the CPU 382. In some contexts, an application that is executed may be said to configure the CPU 382 to do something, e.g., to configure the CPU 382 to perform the function or functions promoted by the subject application. When the CPU 382 is configured in this way by the application, the CPU 382 becomes a specific purpose computer or a specific purpose machine.

The secondary storage 384 is typically comprised of one or more disk drives or tape drives and is used for non-volatile storage of data and as an over-flow data storage device if RAM 388 is not large enough to hold all working data. Secondary storage 384 may be used to store programs which are loaded into RAM 388 when such programs are selected for execution. The ROM 386 is used to store instructions and perhaps data which are read during program execution. ROM 386 is a non-volatile memory device which typically has a small memory capacity relative to the larger memory capacity of secondary storage 384. The RAM 388 is used to store volatile data and perhaps to store instructions. Access to both ROM 386 and RAM 388 is typically faster than to secondary storage 384. The secondary storage 384, the RAM 388, and/or the ROM 386 may be referred to in some contexts as computer readable storage media and/or non-transitory computer readable media. I/O devices 390 may include printers, video monitors, liquid crystal displays (LCDs), touch screen displays, keyboards, keypads, switches, dials, mice, track balls, voice recognizers, card readers, paper tape readers, or other well-known input devices.

The network connectivity devices 392 may take the form of modems, modem banks, Ethernet cards, universal serial bus (USB) interface cards, serial interfaces, token ring cards, fiber distributed data interface (FDDI) cards, wireless local area network (WLAN) cards, radio transceiver cards, and/or other well-known network devices. The network connectivity devices 392 may provide wired communication links and/or wireless communication links (e.g., a first network connectivity device 392 may provide a wired communication link and a second network connectivity device 392 may provide a wireless communication link). Wired communication links may be provided in accordance with Ethernet (IEEE 802.3), Internet protocol (IP), time division multiplex (TDM), data over cable service interface specification (DOCSIS), wavelength division multiplexing (WDM), and/or the like. In an embodiment, the radio transceiver cards may provide wireless communication links using protocols such as code division multiple access (CDMA), global system for mobile communications (GSM), long-term evolution (LTE), WiFi (IEEE 802.11), Bluetooth, Zigbee, narrowband Internet of things (NB IoT), near field communications (NFC), radio frequency identity (RFID). The radio transceiver cards may promote radio communications using 5G, 5G New Radio, or 5G LTE radio communication protocols. These network connectivity devices 392 may enable the processor 382 to communicate with the Internet or one or more intranets. With such a network connection, it is contemplated that the processor 382 might receive information from the network, or might output information to the network in the course of performing the above-described method steps. Such information, which is often represented as a sequence of instructions to be executed using processor 382, may be received from and outputted to the network, for example, in the form of a computer data signal embodied in a carrier wave.

Such information, which may include data or instructions to be executed using processor 382 for example, may be received from and outputted to the network, for example, in the form of a computer data baseband signal or signal embodied in a carrier wave. The baseband signal or signal embedded in the carrier wave, or other types of signals currently used or hereafter developed, may be generated according to several methods well-known to one skilled in the art. The baseband signal and/or signal embedded in the carrier wave may be referred to in some contexts as a transitory signal.

The processor 382 executes instructions, codes, computer programs, scripts which it accesses from hard disk, floppy disk, optical disk (these various disk based systems may all be considered secondary storage 384), flash drive, ROM 386, RAM 388, or the network connectivity devices 392. While only one processor 382 is shown, multiple processors may be present. Thus, while instructions may be discussed as executed by a processor, the instructions may be executed simultaneously, serially, or otherwise executed by one or multiple processors. Instructions, codes, computer programs, scripts, and/or data that may be accessed from the secondary storage 384, for example, hard drives, floppy disks, optical disks, and/or other device, the ROM 386, and/or the RAM 388 may be referred to in some contexts as non-transitory instructions and/or non-transitory information.

In an embodiment, the computer system 380 may comprise two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. In an embodiment, virtualization software may be employed by the computer system 380 to provide the functionality of a number of servers that is not directly bound to the number of computers in the computer system 380. For example, virtualization software may provide twenty virtual servers on four physical computers. In an embodiment, the functionality disclosed above may be provided by executing the application and/or applications in a cloud computing environment. Cloud computing may comprise providing computing services via a network connection using dynamically scalable computing resources. Cloud computing may be supported, at least in part, by virtualization software. A cloud computing environment may be established by an enterprise and/or may be hired on an as-needed basis from a third-party provider. Some cloud computing environments may comprise cloud computing resources owned and operated by the enterprise as well as cloud computing resources hired and/or leased from a third-party provider.

In an embodiment, some or all of the functionality disclosed above may be provided as a computer program product. The computer program product may comprise one or more computer readable storage medium having computer usable program code embodied therein to implement the functionality disclosed above. The computer program product may comprise data structures, executable instructions, and other computer usable program code. The computer program product may be embodied in removable computer storage media and/or non-removable computer storage media. The removable computer readable storage medium may comprise, without limitation, a paper tape, a magnetic tape, magnetic disk, an optical disk, a solid state memory chip, for example analog magnetic tape, compact disk read only memory (CD-ROM) disks, floppy disks, jump drives, digital cards, multimedia cards, and others. The computer program product may be suitable for loading, by the computer system 380, at least portions of the contents of the computer program product to the secondary storage 384, to the ROM 386, to the RAM 388, and/or to other non-volatile memory and volatile memory of the computer system 380. The processor 382 may process the executable instructions and/or data structures in part by directly accessing the computer program product, for example by reading from a CD-ROM disk inserted into a disk drive peripheral of the computer system 380. Alternatively, the processor 382 may process the executable instructions and/or data structures by remotely accessing the computer program product, for example by downloading the executable instructions and/or data structures from a remote server through the network connectivity devices 392. The computer program product may comprise instructions that promote the loading and/or copying of data, data structures, files, and/or executable instructions to the secondary storage 384, to the ROM 386, to the RAM 388, and/or to other non-volatile memory and volatile memory of the computer system 380.

In some contexts, the secondary storage 384, the ROM 386, and the RAM 388 may be referred to as a non-transitory computer readable medium or a computer readable storage media. A dynamic RAM embodiment of the RAM 388, likewise, may be referred to as a non-transitory computer readable medium in that while the dynamic RAM receives electrical power and is operated in accordance with its design, for example during a period of time during which the computer system 380 is turned on and operational, the dynamic RAM stores information that is written to it. Similarly, the processor 382 may comprise an internal RAM, an internal ROM, a cache memory, and/or other internal non-transitory storage blocks, sections, or components that may be referred to in some contexts as non-transitory computer readable media or computer readable storage media.

### ADDITIONAL DISCLOSURE

The following are non-limiting, specific embodiments in accordance with the present disclosure:

A first embodiment, which is a method of evaluating, determining, and/or remediating a stress state of a wellbore isolation barrier, comprising retrieving, by an evaluation application executing on a server, a one or more data sets from a remote data source by a first communication method, wherein the one or more data sets comprise periodic wellbore data indicative of the stress state of the wellbore isolation barrier, and writing, by the evaluation application, the one or more data sets (and optionally a modeled stress state determined therefrom) to non-transitory memory (for example, in a storage server).

A second embodiment, which is the method of the first embodiment, further comprising retrieving, by the evaluation application, a second data set from non-transitory memory in the storage server, (e.g., the second data set typically comprises at least one of the one or more data sets previously stored), and determining, by the evaluation application, a modeled stress state (also referred to as a current stress state) of the wellbore isolation barrier using the second data set.

A third embodiment, which is the method of the first or the second embodiment, further comprising comparing the modeled stress state to a stress threshold, and generating a user notification in response to the modeled stress state exceeding the stress threshold.

A fourth embodiment, which is the method of any of the first through the third embodiments, wherein the periodic wellbore data comprises pressure, temperature, stress, strain, acoustic, or any combination thereof.

A fifth embodiment, which is the method of any of the first through the fourth embodiments, wherein the periodic wellbore data is collected at a time interval of one of milliseconds, seconds, minutes, hours, days, weeks, or months.

A sixth embodiment, which is the method of the third embodiment, wherein the user notification is an email or a text.

A seventh embodiment, which is the method of any of the first through the sixth embodiments, wherein the remote data source is data server, computer, or data storage device located at a wellsite.

An eighth embodiment, which is the method of any of the first through the seventh embodiments, wherein the first communication method is wireless communication from one of a cellular site, satellite communication, or short range radio frequency.

A ninth embodiment, which is the method of the first embodiment, wherein the first communication method is radio frequency.

A tenth embodiment, which is a method of evaluating a stress state of a wellbore isolation barrier, comprising requesting, by an evaluation application executing on a server, one or more data sets from a remote data source by a first communication method, wherein the one or more data sets comprise periodic wellbore data indicative of the stress state of the wellbore isolation barrier, receiving, by the evaluation application, the one or more data sets from the remote data source by a second communication method (e.g., the first and second communication methods can be the same or different), and writing, by the evaluation application, the one or more data sets (and optionally a modeled stress state determined therefrom) to non-transitory memory (for example, in a storage server).

An eleventh embodiment, which is the method of the tenth embodiment, further comprising retrieving, by the evaluation application, a second data set from non-transitory memory in the storage server (e.g., the second data set typically comprises at least one of the one or more data sets previously stored), and determining, by the evaluation application, a modeled stress state (also referred to as a current stress state) of the wellbore isolation barrier using the second data set.

A twelfth embodiment, which is the method of the tenth or the eleventh embodiment, further comprising comparing the modeled stress state to a stress threshold, and generating a user notification in response to the modeled stress state exceeding the stress threshold.

A thirteen embodiment, which is the method of any of the tenth through the twelfth embodiments, wherein the periodic wellbore data comprises pressure, temperature, stress, strain, acoustic, or any combination thereof.

A fourteenth embodiment, which is the method of any of the tenth through the thirteenth embodiments, wherein the periodic wellbore data is collected at a time interval of one of milliseconds, seconds, minutes, hours, days, weeks, or months.

A fifteenth embodiment, which is the method of the twelfth embodiment, wherein the user notification is an email or a text.

A sixteenth embodiment, which is the method of any of the tenth through the fifteenth embodiments, wherein the remote data source is a data server, computer, or data storage device located at a wellsite.

A seventeenth embodiment, which is a method of evaluating a future stress state of a wellbore isolation barrier, comprising requesting, by an evaluation application executing on a server, one or more data sets from a remote data source by a first communication method, wherein the one or more data sets comprise periodic wellbore data indicative of the stress state of the wellbore isolation barrier, receiving, by the evaluation application, the one or more data sets from the remote data source by a second communication method (e.g., the first and second communication methods can be the same or different), and writing, by the evaluation application, the one or more data sets (and optionally a modeled stress state determined therefrom, optionally a future stress state, or both) to non-transitory memory (for example, in a storage server).

An eighteenth embodiment, which is the method of the seventeenth embodiment, further comprising retrieving, by the evaluation application, a second data set from non-transitory memory in the storage server (e.g., the second data set typically comprises at least one of the one or more data sets previously stored), inputting a future stress event and the second data set into the evaluation application, and determining, by the evaluation application, the future stress state of the wellbore isolation barrier using the future stress event and the second data set.

A nineteenth embodiment, which is the method of the seventeenth or the eighteenth embodiment, further comprising comparing the future stress state to a stress threshold, and generating a user notification in response to the future stress state exceeding the stress threshold.

A twentieth embodiment, which is the method of any of the seventeenth through the nineteenth embodiments, wherein the periodic wellbore data comprises pressure, temperature, stress, strain, acoustic, or any combination thereof.

A twenty-first embodiment, which is the method of any of the seventeenth through the twentieth embodiments, wherein the periodic wellbore data is collected at a time interval of one of milliseconds, seconds, minutes, hours, days, weeks, or months.

A twenty-second embodiment, which is the method of the nineteenth embodiment, wherein the user notification is an email or a text.

A twenty-third embodiment, which is the method of any of the seventeenth through the twenty-second embodiments, wherein the remote data source is a data server, computer, or data storage device located at a wellsite.

A twenty-fourth embodiment, which is a method of evaluating a stress state of a wellbore isolation barrier, comprising receiving, by an evaluation application executing on a server, one or more data sets from a remote data source by a first communication method, wherein the one or more data sets comprise periodic wellbore data indicative of the stress state of the wellbore isolation barrier, and writing, by the evaluation application, the one or more data sets (and optionally a modeled stress state determined therefrom, optionally a future stress state, or both) to non-transitory memory (for example, in a storage server).

A twenty-fifth embodiment, which is the method of the twenty-fourth embodiment, further comprising retrieving, by the evaluation application, a second data set from non-transitory memory in the storage server (e.g., the second data set typically comprises at least one of the one or more data sets previously stored), determining, by the evaluation application, a current stress state of the wellbore isolation barrier using the second data set, retrieving one or more previous/past stress states of the wellbore isolation barrier from the non-transitory memory of the storage server, and determining, by the evaluation application, a future stress state of the wellbore isolation barrier by comparing the current stress state to one or more previous/past stress states.

A twenty-sixth embodiment, which is the method of the twenty-fourth or the twenty-fifth embodiment, further comprising comparing the future stress state to a stress threshold, and generating a user notification in response to the future stress state exceeding the stress threshold.

A twenty-seventh embodiment, which is the method of any of the twenty-fourth through the twenty-sixth embodiments, wherein the periodic wellbore data is collected at a time interval of one of milliseconds, seconds, minutes, hours, days, weeks, or months.

A twenty-eighth embodiment, which is the method of the twenty-sixth embodiment, wherein the user notification is an email or a text.

A twenty-ninth embodiment, which is the method of any of the twenty-fourth through the twenty-eighth embodiments, wherein the remote data source is a data server, computer, or data storage device located at a wellsite.

A thirtieth embodiment, which is a method of evaluating a stress state of a wellbore isolation barrier, comprising establishing a queue of evaluation sessions with one or more wellbore isolation barriers to be evaluated by a scheduler application executing on a first server, starting an evaluation application executing on a second server within the evaluation session (e.g., the first and second servers can be the same or different), receiving, by the evaluation application executing on the second server, one or more data sets from a remote data source by a first communication method, wherein the one or more data sets comprise periodic wellbore data indicative of the stress state of the wellbore isolation barrier, writing, by the evaluation application, the one or more data sets (and optionally a modeled stress state determined therefrom, optionally a future stress state, or both) to non-transitory memory (for example, in a storage server), and closing the scheduler application when the queue of evaluation sessions finishes.

A thirty-first embodiment, which is the method of the thirtieth embodiment, further comprising retrieving, by the evaluation application, a second data set from non-transitory memory in the storage server (e.g., the second data set typically comprises at least one of the one or more data sets previously stored), determining, by the evaluation application, a current stress state of the wellbore isolation barrier using the second data set, retrieving one or more previous/past stress states of the wellbore isolation barrier from the non-transitory memory of the storage server, and determining, by the evaluation application, a future stress state of the cement isolation barrier by comparing the current stress state to the one or more previous/past stress states.

A thirty-second embodiment, which is the method of the thirtieth or the thirty-first embodiment, further comprising comparing the future stress state to a stress threshold, and generating a user notification in response to the future stress state exceeding the stress threshold.

A thirty-third embodiment, which is the method of any of the thirtieth through the thirty-second embodiments, wherein the periodic wellbore data is collected at a time interval of one of milliseconds, seconds, minutes, hours, days, weeks, or months.

A thirty-fourth embodiment, which is the method of the thirty-second embodiment, wherein the user notification is an email or a text.

A thirty-fifth embodiment, which is the method of any of the thirtieth through the thirty-fourth embodiments, wherein the remote data source is a data server, computer, or data storage device located at a wellsite.

A thirty-sixth embodiment, which is a method comprising gathering data regarding a status or condition of a barrier disposed within an annulus formed by a conduit disposed within a subterranean well, electronically transmitting the data via a communication network to a location remote from the well or electronically receiving the data via a communication network at a location remote from the well, and analyzing, at the location remote from the wellbore or another location remote from the wellbore, the data to determine a condition of the barrier.

A thirty-seventh embodiment, which is the method of the thirty-sixth embodiment, wherein analyzing the data comprises finite elemental analysis.

A thirty-eighth embodiment, which is the method of the thirty-seventh embodiment, wherein the condition comprises a stress state of the barrier, a load on the barrier, cracking of the barrier, debonding of the barrier from wall of the well, debonding of the barrier from the conduit, plastic deformation of the barrier, plastic failure of the barrier, extrusion of the barrier, or any combination thereof.

A thirty-ninth embodiment, which is the method of the thirty-eighth embodiment, wherein analyzing the data comprises running barrier evaluation software on the data.

A fortieth embodiment, which is the method of the thirty-ninth embodiment, wherein the software can simulate one or more well operations selected from drilling the well, casing the well, cementing the well, pressure testing the well, completing the well, logging the well, injecting fluid into the well, producing fluid from the well, shutting in the well, or any combination thereof for different barrier compositions to optimize design of the well.

A forty-first embodiment, which is the method of the fortieth embodiment, wherein optimize design of the well comprises optimizing one or more of production life of the well, cost of drilling and/or completing the well, cost of maintaining and/or remediating the well over the production life of the well, cost of loss of hydrocarbon (e.g., due to loss of isolation between wellbore zone and resultant interzonal communication, due to water production, etc.), cost of nonproductive time, or any combination thereof.

A forty-second embodiment, which is the method of any of the thirty-sixth through the forty-first embodiments, further comprising comparing a present state of the condition of the barrier to a previous state of the condition of the barrier, comparing the present state of the condition of the barrier to an expected (e.g., design standard) state of the condition of the barrier, or both to determine whether a change in the state of the condition has occurred.

A forty-third embodiment, which is the method of the forty-third embodiment, wherein the change in the state of the condition indicates that remedial action, preventative action, or both are required with respect to the condition of the barrier.

A forty-fourth embodiment, which is the method of any of the thirty-sixth through the forty-first embodiments, further comprising comparing a present state of the condition of the barrier to a previous state of the condition of the barrier, comparing the present state of the condition of the barrier to an expected (e.g., design standard) state of the condition of the barrier, or both to determine an indication that remedial action, preventative action, or both are required with respect to the condition of the barrier.

A forty-fifth embodiment, which is the method of forty-fourth embodiment, wherein the remedial action comprises a squeeze operation (e.g., squeeze cement or squeeze sealant) to place a remedial barrier composition in a location of compromised integrity of the barrier in the well; plugging a portion of the well; fracturing a portion of the well; acidizing a portion of the well; recompleting all or a portion of the well; sidetracking the well and newly completing the sidetracked portion; or any combination thereof.

A forty-sixth embodiment, which is the method of the forty-fourth embodiment, wherein the preventative action comprises modifying an operational parameter of the well (e.g., flow rate of fluid in or out of the well (change production rate), length/duration/frequency of shutdown intervals for the well); modifying a maintenance schedule of the well; modifying a construction parameter of a future well; modifying a completion parameter of a future well; or any combination thereof.

A forty-seventh embodiment, which is the method of any of the thirty-sixth through the forty-sixth embodiments, wherein the gathering, electronically transmitting or receiving, and analyzing are performed at intervals spanning a lifetime of the well.

A forty-eighth embodiment, which is the method of any of the thirty-sixth through the forty-seventh embodiments, wherein the gathering, electronically transmitting or receiving, and analyzing are performed in real-time.

A forty-ninth embodiment, which is the method of the forty-eighth embodiment, wherein gathering the data comprises aggregating data gathered over a plurality of data gathering intervals (e.g., seconds, minutes, days, weeks, months, etc.).

A fiftieth embodiment, which is the method of the forty-eighth embodiment, wherein the gathering, electronically transmitting or receiving, and analyzing are performed automatically at designated data gathering intervals (e.g., seconds, minutes, days, weeks, months, etc.).

A fifty-first embodiment, which is the method of any of the thirty-sixth through the fiftieth embodiments, wherein the well is a natural resource production well (e.g., hydrocarbon production well, water production well), a disposal well (e.g., CO₂ injection well, CO₂ sequestration well, CO₂ storage well, waste-water injection well, chemical disposal well), storage well (e.g., hydrocarbon storage well), a geothermal well, or a well used for carbon capture, sequestration, and/or storage (also referred to as carbon capture, utilization and storage, CCUS), for example for greenhouse gas reduction purposes.

A fifty-second embodiment, which is the method of any of the thirty-sixth through the fifty-first embodiments, wherein the barrier is a cementitious barrier, a non-cementitious barrier (e.g., a sealant such as a polymeric sealant), a mechanical barrier, or combinations thereof.

A fifty-third embodiment, which is the method of any of the thirty-sixth through the fifty-second embodiments, wherein the barrier is a cement sheath disposed within the annulus.

A fifty-fourth embodiment, which is the method of any of the thirty-sixth through the fifty-third embodiments, wherein the data is gathered from one or more sensors positioned within the well proximate the barrier.

A fifty-fifth embodiment, which is the method of fifty-fourth embodiment, wherein the one or more sensors comprise micro electromechanical sensors (MEMS), fiber optic sensors, or both.

A fifty-sixth embodiment, which is the method of the fifty-fourth embodiment, wherein the barrier is a cement sheath disposed within the annulus and wherein the one or more sensors comprise micro electromechanical sensors (MEMS) disposed within the cement sheath, a fiber optic sensor disposed adjacent or on the conduit, or both.

A fifty-seventh embodiment, which is the method of any of the thirty-sixth through the fifty-sixth embodiments, wherein the data comprises temperature, pressure, stress, strain, or any combination thereof.

A fifty-eighth embodiment, which is the method of any of the thirty-sixth through the fifty-seventh embodiments, wherein the data is conveyed (e.g., transmitted via wire or fiber optic, transmitted wirelessly, transmitted via telemetry, etc.) from the sensors in the well proximate the barrier to a data gathering and transmittal device (e.g., computerized data storage and data transceiver) located at the surface of the well.

A fifty-ninth embodiment, which is the method of any one of the fourth, thirteenth, twentieth, or fifty-seventh embodiments, wherein a flow rate of fluid into or out of the wellbore is determined based upon the sensor data, for example a change in temperature data measured at one or more locations downhole.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. A method comprising:
gathering data regarding a status or condition of a barrier disposed within an annulus formed by a conduit disposed within a subterranean well;
electronically transmitting the data via a communication network to a location remote from the well or electronically receiving the data via a communication network at a location remote from the well; and
analyzing, at the location remote from the wellbore or another location remote from the wellbore, the data to determine a condition of the barrier.

2. The method of claim 1, wherein analyzing the data comprises finite elemental analysis.

3. The method of claim 2, wherein the condition comprises a stress state of the barrier, a load on the barrier, cracking of the barrier, debonding of the barrier from wall of the well, debonding of the barrier from the conduit, plastic deformation of the barrier, plastic failure of the barrier, extrusion of the barrier, or any combination thereof.

4. The method of claim 3, wherein analyzing the data comprises running barrier evaluation software on the data.

5. The method of claim 4, wherein the software can simulate one or more well operations selected from drilling the well, casing the well, cementing the well, pressure testing the well, completing the well, logging the well, injecting fluid into the well, producing fluid from the well, shutting in the well, or any combination thereof for different barrier compositions to optimize design of the well.

6. The method of claim 5, wherein optimize design of the well comprises optimizing one or more of production life of the well, cost of drilling and/or completing the well, cost of maintaining and/or remediating the well over the production life of the well, cost of loss of hydrocarbon, cost of nonproductive time, or any combination thereof.

7. The method of claim 1, further comprising comparing a present state of the condition of the barrier to a previous state of the condition of the barrier, comparing the present state of the condition of the barrier to an expected state of the condition of the barrier, or both to determine whether a change in the state of the condition has occurred.

8. The method of claim 7, wherein the change in the state of the condition indicates that remedial action, preventative action, or both are required with respect to the condition of the barrier.

9. The method of claim 1, further comprising comparing a present state of the condition of the barrier to a previous state of the condition of the barrier, comparing the present state of the condition of the barrier to an expected state of the condition of the barrier, or both to determine an indication that remedial action, preventative action, or both are required with respect to the condition of the barrier.

10. The method of claim 9, wherein the remedial action comprises a squeeze operation to place a remedial barrier composition in a location of compromised integrity of the barrier in the well; plugging a portion of the well; fracturing a portion of the well; acidizing a portion of the well; recompleting all or a portion of the well; sidetracking the well and newly completing the sidetracked portion; or any combination thereof.

11. The method of claim 9, wherein the preventative action comprises modifying an operational parameter of the well; modifying a maintenance schedule of the well; modifying a construction parameter of a future well; modifying a completion parameter of a future well; or any combination thereof.

12. The method of claim 1, wherein the gathering, electronically transmitting or receiving, and analyzing are performed at intervals spanning a lifetime of the well.

13. The method of claim 1, wherein the gathering, electronically transmitting or receiving, and analyzing are performed in real-time.

14. The method of claim 13, wherein gathering the data comprises aggregating data gathered over a plurality of data gathering intervals.

15. The method of claim 13, wherein the gathering, electronically transmitting or receiving, and analyzing are performed automatically at designated data gathering intervals.

16. The method of claim 1, wherein the well is a natural resource production well, a disposal well, a storage well, or a geothermal well.

17. The method of claim 1, wherein the barrier is a cementitious barrier, a non-cementitious barrier, a mechanical barrier, or combinations thereof.

18. The method of claim 1, wherein the barrier is a cement sheath disposed within the annulus.

19. The method of claim 1, wherein the data is gathered from one or more sensors positioned within the well proximate the barrier.

20. The method of claim 19, wherein the one or more sensors comprise micro electromechanical sensors (MEMS), fiber optic sensors, or both.

21. The method of claim 19, wherein the barrier is a cement sheath disposed within the annulus and wherein the one or more sensors comprise micro electromechanical sensors (MEMS) disposed within the cement sheath, a fiber optic sensor disposed adjacent or on the conduit, or both.

22. The method of claim 21, wherein the data comprises temperature, pressure, acoustic, stress, strain, or any combination thereof.

23. The method of claim 22, wherein the data is conveyed from the sensors in the well proximate the barrier to a data gathering and transmittal device located at the surface of the well.
